(19) United States
(12) Patent Application Publication
(10) Pub. No.: US 2026/0013250 A1
(43) Pub. Date: Jan. 8, 2026

(54) SOLID-STATE IMAGING DEVICE

(71) Applicant: Samsung Electronics Co., Ltd., Suwon-si (KR)

(72) Inventor: Kazufumi SHIOZAWA, Yokohama (JP)

(73) Assignee: Samsung Electronics Co., Ltd., Suwon-si (KR)

(21) Appl. No.: 19/257,827

(22) Filed: Jul. 2, 2025

(30) Foreign Application Priority Data
Jul. 5, 2024 (JP) 2024-108910
Mar. 18, 2025 (KR) 10-2025-0034898

(51) Int. Cl. H10F 39/00; H10F 39/18

(52) U.S. Cl. CPC H10F 39/806; H10F 39/18; H10F 39/8063; H10F 39/811

(57) ABSTRACT

Provided is a solid-state imaging device including a plurality of pixels, each of the plurality of pixels including a photoelectric conversion unit configured to generate electric charges from incident light, an on-chip lens on an upper side of the photoelectric conversion unit, a plurality of wiring layers under a lower side of the photoelectric conversion unit, the plurality of wiring layers configured to extract the electric charges generated by the photoelectric conversion unit, an interlayer dielectric film between the plurality of wiring layers and between the plurality of wiring layers and the photoelectric conversion unit, and a first periodic structure unit including metal layers and dielectric layers alternating sequentially in a circumferential direction along a periphery of the photoelectric conversion unit, at least a portion of the first periodic structure unit in a region between the photoelectric conversion unit and the plurality of wiring layers.

### CROSS-REFERENCE TO RELATED APPLICATIONS

This application is based on and claims priority under 35 U.S.C. § 119 to Japanese Patent Application No. 2024-108910, filed on Jul. 5, 2024, in the Japan Patent Office, and Korean Patent Application No. 10-2025-0034898, filed on Mar. 18, 2025, in the Korean Intellectual Property Office, the disclosures of each of which are incorporated by reference herein in their entirety.

### BACKGROUND

The inventive concepts relate to solid-state imaging devices.

Solid-state imaging devices may be mounted onto various mobile terminals such as digital cameras and mobile phones.

In general, the solid-state imaging devices have photoelectric conversion units arranged two-dimensionally, at least one on-chip lens provided on a first side of the photoelectric conversion units where light is incident, and a wiring layer provided on a side opposite to the first side (where the on-chip lens of the photoelectric conversion unit is provided (see, for example, Non-Patent Document 1 (2023 Symposium on VLSI Technology and Circuits Digest of Technical Papers JFS2-2)).

In the solid-state imaging devices, in order to meet the demands for quality, standards, and efficiency, it is generally beneficial for quantum efficiency (QE) to exceed a certain value. Additionally, it is beneficial for modulation transfer function (MTF), which is an evaluation index of resolution, to exceed a certain value. Additionally, MTF may be obtained by comparing QE of a certain pixel to QE of an adjacent pixel caused by light leaking from that pixel to the adjacent pixel (color mixing).

### SUMMARY

In the solid-state imaging device of the Non-Patent Document 1, a shield ring is provided in a pixel boundary region within an interlayer dielectric film, which is located between a first wiring layer closest to the photoelectric conversion unit among the wiring layers and the photoelectric conversion unit. The shield ring is formed continuously in the circumferential direction thereof. By providing the shield ring in this way, leaking of light to adjacent pixels through the interlayer dielectric film may be protected against (e.g., may be prevented and/or suppressed). Due to the presence of the shield ring, color mixing may decrease and thus a modulation transfer function (MTF) value may increase. However, since there is a lot of light absorption by the shield ring, quantum efficiency (QE) decreases, which is not desirable.

The inventive concepts have been made to solve the above-mentioned issues, and have objects to provide a solid-state imaging device having QE and MTF exceeding predetermined values.

The above-mentioned objects of the inventive concepts may be achieved by the followings:
(1) As a solid-state imaging device including a plurality of pixels included in a pixel region, the solid-state imaging device including a plurality of two-dimensionally arranged photoelectric conversion units, an on-chip lens on one side of each of the photoelectric conversion units, wiring layers on the other side of the photoelectric conversion units, and a first periodic structure unit in a pixel boundary region within an interlayer dielectric film positioned between a first wiring layer closest to the photoelectric conversion units among the wiring layers and the photoelectric conversion units, the first periodic structure unit having periodicity in a two-dimensional direction, the two-dimensional direction orthogonal to a stacking direction, wherein the first periodic structure unit may include a metal layer including a metal and a dielectric layer including a dielectric material.
(2) In the solid-state imaging device described in (1), a period of the metal layer of the first periodic structure unit may be less than a wavelength of light received by the photoelectric conversion unit, and light irradiated to the first periodic structure unit may be set to generate diffracted light in the first periodic structure unit.
(3) In the solid-state imaging device described in (1) or (2), a shape of the metal layer of the first periodic structure unit may be an island shape in which each of metal layers is independently arranged.
(4) In the solid-state imaging device described in any one of (1) to (3), a height of the first periodic structure unit may be the same as a distance from the first wiring layer to the photoelectric conversion unit.
(5) In the solid-state imaging device described in any one of (1) to (3), a height of the metal layer of the first periodic structure unit may be greater than the distance from the first wiring layer to the photoelectric conversion unit and less than a distance from the first wiring layer to the on-chip lens.
(6) In the solid-state imaging device described in any one of (1) to (3), the wiring layer may include a second wiring layer provided on the other side of the first wiring layer, and the height of the metal layer of the first periodic structure unit may be the same as a distance from the second wiring layer to the photoelectric conversion unit.
(7) In the solid-state imaging device described in any one of (1) to (3), the wiring layer may include a second wiring layer provided on the other side of the first wiring layer, and the height of the metal layer of the first periodic structure unit may be greater than the distance from the second wiring layer to the photoelectric conversion unit and less than a distance from the second wiring layer to the on-chip lens.
(8) In the solid-state imaging device described in any one of (1) to (7), the wiring layer may include a third wiring layer provided on the other side of the first wiring layer, and the height of the metal layer of the first periodic structure unit may be the same as a distance from the third wiring layer to the photoelectric conversion unit.
(9) In the solid-state imaging device described in any one of (1) to (7), the wiring layer may include a second wiring layer provided on the other side of the first wiring layer, and the height of the metal layer of the first periodic structure unit may be greater than the distance from the third wiring layer to the photoelectric conversion unit and less than the distance from the third wiring layer to the on-chip lens.
(10) In the solid-state imaging device described in any one of (1) to (9), the height of the metal layer of the first periodic structure unit may be different for each independent island of the metal layer.
(11) In the solid-state imaging device described in any one of (1) to (10), a second periodic structure unit may be further provided within the interlayer dielectric film positioned between the first wiring layer and another wiring layer provided on the other side of the first wiring layer, and the second periodic structure unit may have periodicity in a two-dimensional direction orthogonal to a stacking direction in a pixel boundary region within the interlayer dielectric film, wherein the second periodic structure unit may include a metal layer including a metal and a dielectric layer including a dielectric material.
(12) In the solid-state imaging device described in (11), a period of the metal layer of the second periodic structure unit may be less than the wavelength of light received by the photoelectric conversion unit, and light irradiated to the second periodic structure unit may be set to generate diffracted light in the second periodic structure unit.
(13) In the solid-state imaging device described in (11) or (12), the second periodic structure unit may have the same period as the first periodic structure unit.
(14) In the solid-state imaging device described in any one of (11) to (13), the height of the second periodic structure unit may be the same as a distance from the first wiring layer to the another wiring layer.
(15) In the solid-state imaging device described in any one of (1) to (14), periods of the first periodic structure unit and the second periodic structure unit may be different from each other in a central portion and a peripheral portion of a pixel array.

In addition, the objects of the inventive concepts are achieved by the following means.

According to an aspect of the inventive concepts, there is provided a solid-state imaging device including a plurality of pixels, each of the plurality of pixels including a photoelectric conversion unit configured to generate electric charges from incident light, an on-chip lens on an upper side of the photoelectric conversion unit, a plurality of wiring layers under a lower side of the photoelectric conversion unit, the plurality of wiring layers configured to extract the electric charges generated by the photoelectric conversion unit, an interlayer dielectric film between the plurality of wiring layers and between the plurality of wiring layers and the photoelectric conversion unit, and a first periodic structure unit including metal layers and dielectric layers alternating sequentially in a circumferential direction along a periphery of the photoelectric conversion unit, at least a portion of the first periodic structure unit in a region between the photoelectric conversion unit and the plurality of wiring layers.

According to an aspect of the inventive concepts, there is provided a solid-state imaging device including a pixel region that includes a plurality of pixels arranged in two dimensions, the solid-state imaging device including photoelectric conversion units, each of the photoelectric conversion units in a corresponding pixel of the plurality of pixels, an insulating film between the photoelectric conversion units, the insulating film configured to insulate each of the plurality of pixels from adjacent pixels of the plurality of pixels, on-chip lenses, each of the on-chip lenses on an upper side of a corresponding one of the photoelectric conversion units, a plurality of wiring layers below the photoelectric conversion units, the plurality of wiring layers configured to extracting electric charges generated by the photoelectric conversion units from incident light, an interlayer dielectric film between the plurality of wiring layers and between the plurality of wiring layers and the photoelectric conversion unit, and a first periodic structure unit in a region between the photoelectric conversion units and the plurality of wiring layers, the first periodic structure unit comprising metal layers spaced apart from each along a pixel boundary region between the adjacent pixels.

According to an aspect of the inventive concepts, there is provided a solid-state imaging device including a pixel region that includes a plurality of pixels arranged in two dimensions, the solid-state imaging device including photoelectric conversion units, each of the photoelectric conversion units in a corresponding pixel of the plurality of pixels, an insulating film between the photoelectric conversion units, the insulating film configured to insulate each of the plurality of pixels from adjacent pixels of the plurality of pixels, on-chip lenses, each of the on-chip lenses on an upper side of a corresponding one of the photoelectric conversion units, a plurality of wiring layers below on a lower side of the photoelectric conversion units, the plurality of wiring layers configured to and extracting electric charges generated by the photoelectric conversion units from incident light, an interlayer dielectric film between the plurality of wiring layers and between the plurality of wiring layers and the photoelectric conversion unit, and a first periodic structure unit in a region between the photoelectric conversion units and the plurality of wiring layers, the first periodic structure unit comprising metal layers spaced apart from each other along a pixel boundary region between the adjacent pixels, wherein a period of the metal layers of the first periodic structure in a central portion of the pixel region is different from a period of the metal layers of the first periodic structure in a peripheral portion of the pixel region.

### BRIEF DESCRIPTION OF THE DRAWINGS

Embodiments will be more clearly understood from the following detailed description taken in conjunction with the accompanying drawings in which:

FIG. 1 is a plan view showing a pixel region composed of a plurality of pixels in a solid-state imaging device according to at least one example embodiment;

FIG. 2 is a front cross-sectional view showing a solid-state imaging device according to at least one example embodiment;

FIG. 3 is a schematic cross-sectional view showing one pixel of a solid-state imaging device;

FIG. 4 is a plan view taken along line 4-4 of FIG. 3;

FIG. 5 is a cross-sectional view taken along line 5-5 of FIG. 4;

FIG. 6 is a cross-sectional view taken along line 6-6 of FIG. 4;

FIG. 7 is a diagram for explaining the pitch, width, and gap of a first periodic structure unit;

FIG. 8 is a diagram of a solid-state imaging device according to Comparative Example 1, which corresponds to FIG. 4;

FIG. 9 is a diagram of a solid-state imaging device according to Comparative Example 2, which corresponds to FIG. 3;

FIG. 10 is a graph showing values of quantum efficiency (QE) and modulation transfer function (MTF) of solid-state imaging devices according to Comparative Example 1, Comparative Example 2, and at least one example embodiment;

FIG. 11 is a diagram of a solid-state imaging device according to Variant Example 1, which corresponds to FIG. 4;

FIG. 12 is a diagram of a solid-state imaging device according to Variant Example 2, which corresponds to FIG. 4;

FIG. 13 is a diagram of a solid-state imaging device according to Variant Example 3, which corresponds to FIG. 4;

FIG. 14 is a diagram of a solid-state imaging device according to Variant Example 4, which corresponds to FIG. 6;

FIG. 15 is a diagram of a solid-state imaging device according to Variant Example 5, which corresponds to FIG. 6;

FIG. 16 is a diagram of a solid-state imaging device according to Variant Example 6, which corresponds to FIG. 6;

FIG. 17 is a diagram of a solid-state imaging device according to Variant Example 7, which corresponds to FIG. 6;

FIG. 18 is a diagram of a solid-state imaging device according to Variant Example 8, which corresponds to FIG. 6;

FIG. 19 is a diagram of a solid-state imaging device according to Variant Example 9, which corresponds to FIG. 6;

FIG. 20 is a diagram of a solid-state imaging device according to Variant Example 10, which corresponds to FIG. 6;

FIG. 21 is a diagram of a solid-state imaging device according to Variant Example 11, which corresponds to FIG. 6;

FIG. 22 is a diagram of a solid-state imaging device according to Variant Example 12, which corresponds to FIG. 6;

FIG. 23 is a diagram of a solid-state imaging device according to Variant Example 13, which corresponds to FIG. 6;

FIG. 24 is a diagram of a solid-state imaging device according to Variant Example 14, which corresponds to FIG. 6; and

FIG. 25 is a diagram for explaining a solid-state imaging device according to Variant Example 15.

### DETAILED DESCRIPTION OF THE EMBODIMENTS

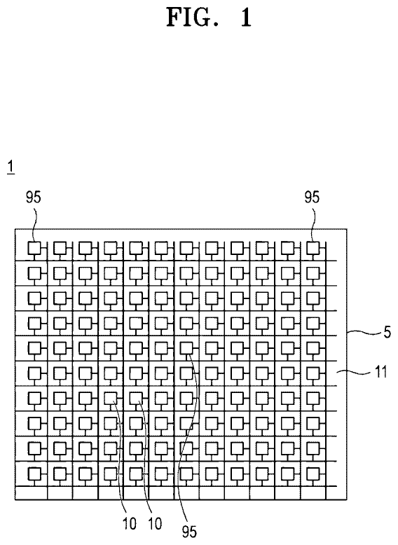

Hereinafter, embodiments will be described with reference to FIGS. 1 to 7. In addition, dimension ratios of the drawings may be exaggerated for the sake of explanation and may differ from actual ratios thereof. Spatially relative terms, such as lower, upper, above, below, etc. are represented herein based on the direction illustrated in the drawings and may be represented otherwise when the orientation of the corresponding object changes. In other words, such spatially relative terms are intended to encompass different orientations of the device in use or operation in addition to the orientation depicted in the figures, such that the device may be otherwise oriented (rotated 90 degrees or at other orientations) and the spatially relative terms used herein interpreted accordingly.

Additionally, when the terms “about” or “substantially” are used in this specification in connection with a numerical value and/or geometric term, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Further, whenever a range of values is enumerated, the range includes all values within the range, and may further include the boundaries of the range. Accordingly, a value being “in” a range of “X” to “Y” includes any value between X and Y, including X and Y, unless expressly indicated otherwise.

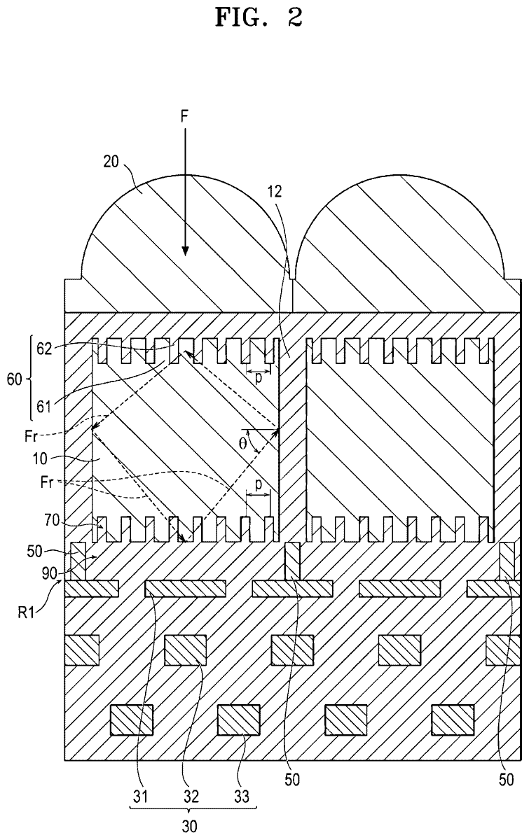

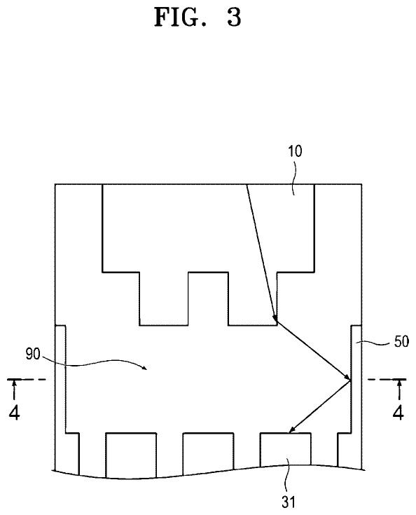

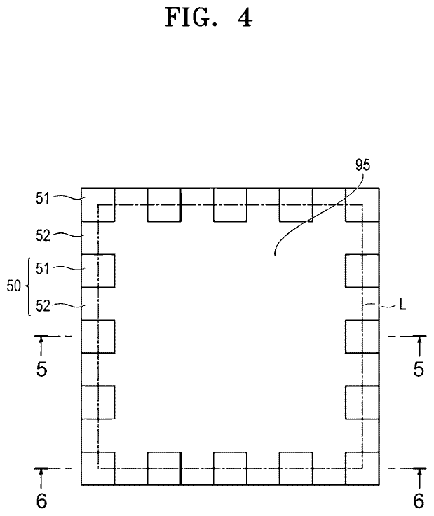

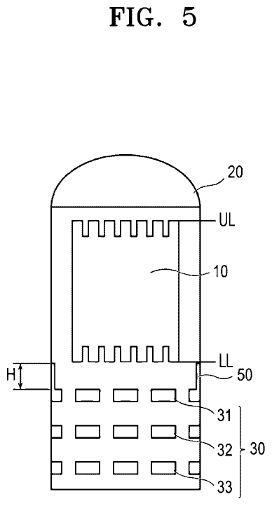

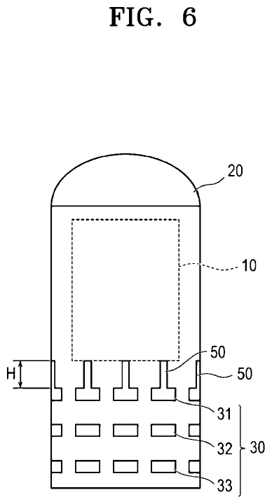

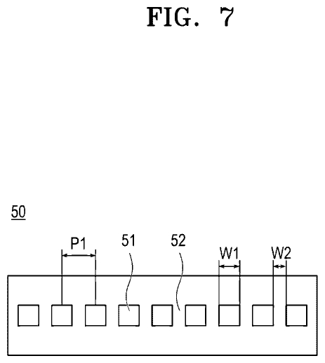

FIG. 1 is a plan view showing a pixel region 5 composed of a plurality of pixels 95 in a solid-state imaging device 1 according to at least one example embodiment. FIG. 2 is a front cross-sectional view showing the solid-state imaging device 1 according to at least one example embodiment. FIG. 3 is a partial enlarged view schematically showing a portion of FIG. 2. FIG. 4 is a plan view taken along line 4-4 of FIG. 3. FIG. 5 is a cross-sectional view taken along line 5-5 of FIG. 4. FIG. 6 is a cross-sectional view taken along line 6-6 of FIG. 4. FIG. 7 is a diagram for explaining the pitch, width, and gap of a first periodic structure unit 50.

The solid-state imaging device 1 according to the at least one example embodiment may be a complementary metal oxide semiconductor (CMOS)-type solid-state imaging device. The solid-state imaging device 1 may be configured to be connected to and controlled by a host (not illustrated). For example, the host may be and/or include processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The host may be configured to control the operations of the solid-state imaging device 1 and/or to receive image data from the solid-state imaging device 1.

In solid-state imaging devices, it is beneficial for the quantum efficiency (QE) to exceed a certain value. QE is a ratio of the number of electrons generated to the number of incident photons. In addition, in a solid-state imaging device, it is beneficial for modulation transfer function (MTF), which is the evaluation index of resolution, to exceed a certain value. MTF may be obtained by comparing QE of a certain pixel to QE of an adjacent pixel caused by light leaking from that pixel to the adjacent pixel.

The solid-state imaging device 1 may include a plurality of pixels 95 in the pixel region 5, as illustrated in FIG. 1. As illustrated in FIGS. 1 and 2, the solid-state imaging device 1 may include a plurality of photoelectric conversion units 10 arranged two-dimensionally, at least one on-chip lens 20 provided above the photoelectric conversion unit 10, a wiring layer 30 provided below the photoelectric conversion units 10, the first periodic structure unit 50 provided between the wiring layer 30 and the photoelectric conversion units 10, and a periodic structure 60 provided between the photoelectric conversion units 10 and the on-chip lens 20. The photoelectric conversion unit 10 may also be referred to as a “photoelectric converter”. The first periodic structure unit 50 includes a group of first periodic structures and may also be referred to as a first group of periodic structures. Each component will be further described below.

### <Photoelectric Conversion Unit 10>

The photoelectric conversion unit 10 may be provided in multiple units within a substrate 11, as shown in FIG. 1. The substrate 11 may be and/or include a semiconductor substrate, such as a silicon (Si) substrate, a geranium (Ge) substate, an SiGe substrate, and/or the like. The semiconductor substrate, for example, may include an elemental and/or compound semiconductor material. As shown in FIG. 2, a lower surface of the substrate 11 may be a surface of a front side of the substrate 11, and an upper surface of the substrate 11 may be a surface of a back side of the substrate 11. The solid-state imaging device 1 according to the at least one example embodiment is a so-called back-illuminated type, so the on-chip lens 20 may be provided on the back side of the substrate 11. The surface of the back side of the substrate 11 may be the surface where light enters the substrate 11. On the other hand, the wiring layer 30 may be provided on and/or in the surface of the front side of the substrate 11. A thickness of the substrate 11 may be, for example, about 1 micrometer (μm) or more and/or about 10 μm or less. For example, in at least some embodiments, the thickness of substrate 11 may be in the range of about 1 μm to about 10 μm.

The photoelectric conversion unit 10 may be provided for each pixel 95 in the substrate 11. The photoelectric conversion unit 10 may include a p-type semiconductor region and an n-type semiconductor region. In the photoelectric conversion unit 10, a photodiode may be realized by a P-N junction between the p-type semiconductor region and the n-type semiconductor region, and the photodiode may convert light into electric charges. The photoelectric conversion unit 10 may be configured to receive light incident on the on-chip lens 20, generate signal charges according to the amount of light received, and accumulate the generated signal charges in the n-type semiconductor region.

Adjacent photoelectric conversion units 10 may be separated from each other by an insulating film 12, as shown in FIG. 2. Therefore, the insulating film 12 may protect against (e.g., prevent, suppress, and/or mitigate) signal charges from leak from one pixel 95 to an adjacent pixel 95. Therefore, when signal charges exceeding the saturation charge amount occur, leakage of signal charges from one photoelectric conversion unit 10 to an adjacent photoelectric conversion unit 10 may decrease. Accordingly, the color mixing between pixels may be suppressed, thereby improving the MTF value. Materials constituting the insulating film 12 may include a silicon oxide film, a silicon nitride film, a silicon oxynitride film, a resin film, etc. In at least some example embodiments, the insulating film 12 may be deposited in a trench (not illustrated) formed in the substrate 11 (e.g., between the photoelectric conversion units 10). Additionally, the insulating film 12 may be a film that does not have a positive fixed charge or a film with a small amount of positive fixed charge.

Additionally, a fixed charge film (not illustrated) may be between adjacent photoelectric conversion units 10. The fixed charge film may reduce the occurrence of dark current and reduce noise. A material constituting the fixed charge film may include, for example, an oxide film and/or a nitride film containing at least one of hafnium (Hf), aluminum (Al), zirconium (Zr), tantalum (Ta), titanium (Ti), and/or the like. Examples of methods of forming the fixed charge film may include chemical vapor deposition (CVD), sputtering, and atomic layer deposition (ALD), etc.

### <On-Chip Lens 20>

The on-chip lens 20 may be formed for each pixel 95. The on-chip lens 20 is configured to collect incident light. Light F collected by the on-chip lens 20 may enter the photoelectric conversion unit 10.

In addition, at least some embodiments, a light-shielding film and/or a flattening film, etc. may be provided between the on-chip lens 20 and the photoelectric conversion unit 10.

### <Wiring Layer 30>

The wiring layer 30 may include a plurality of wiring layers in a stacking direction (e.g., a vertical direction), as illustrated in FIG. 2. The wiring layer 30 may include a conductive material, such as at least one of a metal, a conductive oxide, a conductive polymer, a conductive nitride, and/or the like. The wiring layer 30 may be disposed in an interlayer dielectric film 90. The wiring layer 30 may include a plurality of layers (e.g., a first wiring layer 31, a second wiring layer 32, and a third wiring layer 33). In addition, there is no particular limitation on the number of layers in the wiring layers 30 provided in one solid-state imaging device 1, the arrangement in a two-dimensional direction, the cross-sectional shape in the stacking direction, etc., and they may be arbitrarily changed. That is, a fourth wiring layer, a fifth wiring layer, etc. may be arranged below the third wiring layer 33 in the stacking direction.

The first wiring layer 31, the second wiring layer 32, and the third wiring layer 33 may be configured to extract the signal charges generated and accumulated by the photoelectric conversion unit 10, as a pixel signal. The first wiring layer 31, the second wiring layer 32, and the third wiring layer 33 may output the pixel signal extracted.

### <First Periodic Structure Unit 50>

The first periodic structure unit 50 may be provided in a pixel boundary region R1 within the interlayer dielectric film 90 located between the first wiring layer 31 closest to the photoelectric conversion unit 10 among the wiring layers 30 and the photoelectric conversion unit 10, as shown in FIGS. 2 and 3.

The first periodic structure unit 50 may have periodicity in the two-dimensional directions which are orthogonal to the stacking direction (e.g., the vertical direction), as shown in FIG. 4. The first periodic structure unit 50 may include a metal layer 51 including a metal and a dielectric layer 52 including a dielectric material, as shown in FIG. 4. The metal layer 51 and the dielectric layer 52 may be provided in multiple units, as shown in FIG. 4.

The metal layer 51 may be provided intermittently along a circumferential direction at equal intervals, as shown in FIG. 4. The shape of the metal layer 51 may be an island shape in which each metal layer 51 is independently arranged, and/or may be a square shape or a rectangular shape, but is not limited thereto. For example, the metal layer 51 may have a polygon shape in a plan view. The metal layer 51 may be arranged on a pixel boundary line L between adjacent pixels 95, as shown in FIG. 4.

The dielectric layer 52 may be arranged between metal layers 51 configured in the island shape, as shown in FIGS. 4 to 6. The dielectric layer 52 may be arranged to partition adjacent metal layers 51. In at least some embodiments, an inner edge of the dielectric layer 52 may define the pixel boundary line L, and the metal layer 51 may, in the plan view, extend past the pixel boundary line.

As shown in FIG. 7, a width W1 of the metal layer 51 in the first periodic structure unit 50 may be greater than a width W2 of the dielectric layer 52. According to this configuration, an area where the metal layer 51 contributing to reflection is arranged may be greater than an area where the dielectric layer 52 is arranged, so that incident light may be suitably reflected in the first periodic structure unit 50.

In at least some embodiments, the pitch P1 of the metal layer 51 along a horizontal plane direction satisfies the following Mathematical Formula 1, wherein n1 is a refractive index of the dielectric layer 52, 0 is an incident angle of incident light, m is a natural number, λ is a wavelength of the incident light, and n2 is a refractive index of the metal layer 51.

$$n 1 sin θ \pm \frac{m λ}{p} = \sqrt{\frac{n {1}^{2} \times n {2}^{2}}{n {1}^{2} + n {2}^{2}}} \qquad [ Mathematical Formula 1 ]$$

By satisfying this Mathematical Formula 1, when incident light is incident on the first periodic structure unit 50, diffracted light diffracted in the metal layer 51 may move in the horizontal direction in the first periodic structure unit 50, to generate an evanescent wave. This may cause an increase in light intensity due to surface plasmon resonance, and the incident light may be more suitably reflected in the first periodic structure unit 50.

In other words, the pitch P1 of the metal layer 51 of the first periodic structure unit 50 may vary depending on the wavelength λ and the incident angle θ of light received by the photoelectric conversion unit 10, and may be set to be less than the wavelength λ, and further, may be set such that the light irradiated to the first periodic structure unit 50 generates diffracted light in the first periodic structure unit 50. Therefore, the effect of surface plasmon resonance described above may be achieved. In addition, the reflectivity may increase by making the pitch P1 of the metal layer 51 of the first periodic structure unit 50 to be less than the wavelength λ. When the wavelength of incident light is 940 nanometers (nm), the pitch P1 of the metal layer 51 may be, for example, in a range of about 200 nm and about 1,000 nm, for example, about 400 nm or more and/or about 500 nm or less. In at least some example embodiments, the pitch P1 may be different based on the wavelength λ. For example, a color filter may be configured to filter the incident light and to provide a selected wavelength λ to the photoelectric conversion unit 10, and the pitch P1 of the corresponding first periodic structure may be selected based on the selected wavelength λ.

In at least some embodiments, the height H of the metal layer 51 of the first periodic structure unit 50 may be the same as and/or substantially similar to a distance from the first wiring layer 31 to the photoelectric conversion unit 10, as shown in FIGS. 5 and 6. In at least some embodiments, a vertical level of a top of the metal layer 51 of the first periodic structure unit 50 may be higher than a vertical level LL of a bottom of the photoelectric conversion unit 10 and lower than a vertical level UL of a top of the photoelectric conversion unit 10.

A volume of the metal layer 51 may be set according to the desired QE. When the volume of the metal layer 51 is relatively large, QE may decrease while MTF may increase. Additionally, when the volume of the metal layer 51 is relatively small, QE may increase while MTF may decrease.

A material constituting the metal layer 51 may include, for example, tungsten, aluminum, copper, etc.

A material constituting the dielectric layer 52 may include, for example, one or more of silicon dioxide (SiO₂), silicon nitride (SiN), aluminum oxide (AlO), tantalum oxide (TaO), titanium nitride (TiN), titanium oxide (TiO), etc.

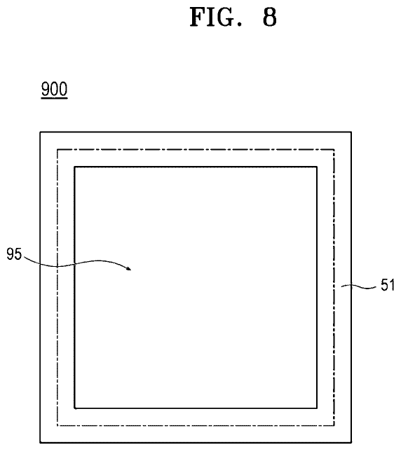

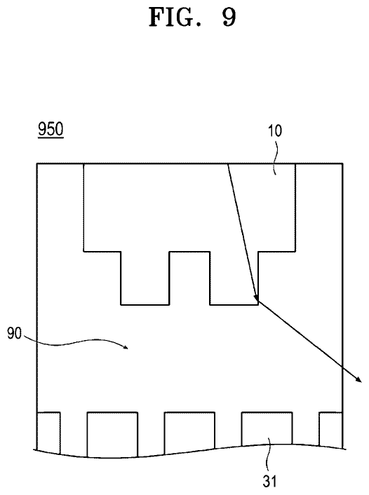

Hereinafter, configurations of solid-state imaging devices according to Comparative Examples 1 and 2 will be described with reference to FIGS. 8 and 9. FIG. 8 is a diagram of a solid-state imaging device 900 according to Comparative Example 1, which corresponds to FIG. 4, and FIG. 9 is a diagram of a solid-state imaging device 950 according to Comparative Example 2, which corresponds to FIG. 3.

As illustrated in FIG. 8, the solid-state imaging device 900 of Comparative Example 1 has a metal layer 51 formed continuously along the circumferential direction, unlike the solid-state imaging device 1 of the at least one example embodiment. In addition, as illustrated in FIG. 9, the solid-state imaging device 950 of Comparative Example 2 does not have the first periodic structure unit 50 and no metal layer is formed on the interlayer dielectric film 90, unlike the solid-state imaging device 1 of the at least one example embodiment.

In the case of the solid-state imaging device 900 of Comparative Example 1, since the metal layer 51 is formed continuously along the circumferential direction in the interlayer dielectric film 90, color mixing may decrease by protecting against light leakage to adjacent pixels, thereby increasing the MTF. On the other hand, the metal layer 51 has a large light absorption effect, so the QE decreases.

In addition, in the case of the solid-state imaging device 950 of Comparative Example 2, since no metal layer is formed on the interlayer dielectric film 90, light absorption may decrease and QE may increase. On the other hand, since the dielectric layer allows light to travel, light may travel to adjacent pixels, causing color mixing and lowering MTF.

In contrast, in the case of the solid-state imaging device 1 (e.g., according to the at least one example embodiment), since the first periodic structure unit 50 may be configured such that the metal layer 51 and the dielectric layer 52 may be alternately and sequentially provided in the circumferential direction along a circumference of the photoelectric conversion unit 10, the QE of the solid-state imaging device may be greater than the Comparative Example 1, while the MTF of the solid-state imaging device may also be greater than the Comparative Example 2.

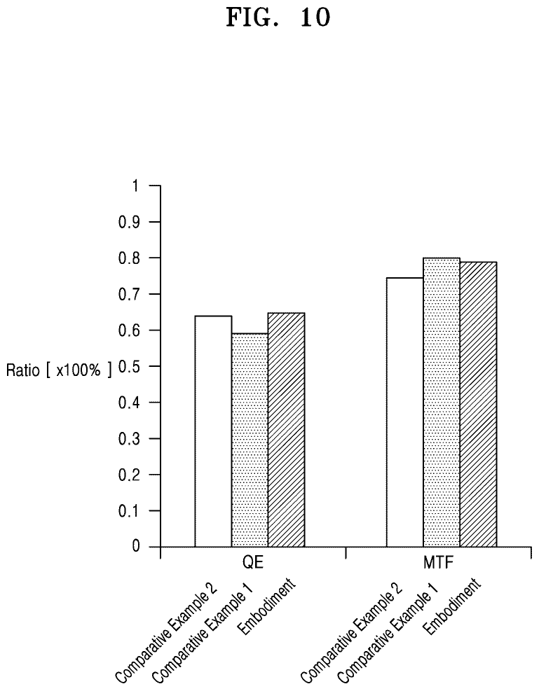

With reference to FIG. 10, simulation results for QE and MTF values of the solid-state imaging device 1 according to the at least one example embodiment, the solid-state imaging device 900 according to Comparative Example 1, and the solid-state imaging device 950 according to Comparative Example 2 are described. FIG. 10 is a graph showing QE and MTF values of solid-state imaging devices according to Comparative Example 1, Comparative Example 2, and the at least one example embodiment.

As known from FIG. 10, QE in the solid-state imaging device 1 of the at least one example embodiment is substantially equivalent to QE in the solid-state imaging device 950 of Comparative Example 2, and MTF is approximately equivalent to MTF in the solid-state imaging device 900 of Comparative Example 1. Therefore, the solid-state imaging device 1 according to the at least one example embodiment may have both high QE of the solid-state imaging device 950 according to Comparative Example 2 and high MTF of the solid-state imaging device 900 according to Comparative Example 1.

### <Periodic Structure 60>

Next, a configuration of the upper periodic structure 60 of the photoelectric conversion unit 10 will be described with reference to FIG. 2. The upper periodic structure 60 may be provided over a certain range in the vertical direction of the photoelectric conversion unit 10. In the at least one example embodiment, as shown in FIG. 2, the upper periodic structure 60 may include a second layer 62 extending vertically downward in the stacking direction (e.g., the vertical direction) of the photoelectric conversion unit 10 and a first layer 61 not extending vertically downward between adjacent second layers 62. The upper periodic structure 60 may include a region in which the first layer 61 and the second layer 62 are alternately and sequentially arranged two-dimensionally in the horizontal direction orthogonal to the vertical direction.

The upper periodic structure 60 may have periodicity in the two-dimensional direction (e.g., a plane direction) in the horizontal direction orthogonal to the vertical direction, as shown in FIG. 2. The upper periodic structure 60 may include one or more of the first layers 61 and one or more of the second layers 62 with the second layers having a lower refractive index of light than the first layers 61, as shown in FIG. 2. The first layer 61 and the second layer 62 may be provided in multiple units (or groups). The upper periodic structure 60 may include the first layer 61 and the second layer 62 arranged regularly to have a period p in the two-dimensional direction. The first layer 61 and the second layer 62 may be arranged over an entire upper side of the photoelectric conversion unit 10 in the two-dimensional direction. In some embodiments, the first layer 61 and the second layer 62 may be arranged over a portion of the upper side of the photoelectric conversion unit 10 in the two-dimensional direction.

The “difference in refractive index of light” between the first layer 61 and the second layer 62 may be defined, for example, by the physical properties (e.g., dielectric constant) of constituent materials of the first and second layers 61 and 62.

As the constituent materials of the first and second layers 61 and 62 that may realize the desired difference in refractive index of light, for example, the following combination of materials may be selected.

The constituent material of the first layer 61 may include, for example, at least one of silicon (Si), germanium (Ge), indium gallium arsenide (InGaAs), and/or the like.

When the first layer 61 is composed of one of the constituent materials listed above, the second layer 62 may include, for example, an insulator, such as one or more of SiO₂, SiN, AlO, TaO, TIN, TiO, and/or the like.

The effect of arranging the upper periodic structure 60 (enhancement of QE due to diffracted light) in this way will be described below.

The upper periodic structure 60 may include the first layer 61 and the second layer 62 arranged regularly to have a period p in the two-dimensional direction. As shown in FIG. 2, incident light F may be incident on the upper periodic structure 60 from an upper side of the photoelectric conversion unit 10. The upper periodic structure 60 may generate diffracted light Fr. The upper periodic structure 60 may have a certain period p in the two-dimensional direction. Therefore, the upper periodic structure 60 may generate the diffracted light Fr at each portions thereof in the two-dimensional direction according to the period p.

As shown in FIG. 2, the diffracted light Fr generated by the upper periodic structure 60 may not travel in the shortest straight line distance from the top to the bottom inside the photoelectric conversion unit 10, but may travel in an oblique direction inside the photoelectric conversion unit 10. Therefore, an optical path length of light in the pixel 95, in which the photoelectric conversion unit 10 may convert light into electric charges, may increase, compared to a case in which the diffracted light Fr is not generated. The amount of light absorbed in the photoelectric conversion unit 10 in the pixel 95 may increase (e.g., by increasing the optical path length of the light in which the photoelectric conversion unit 10 may convert light into electric charges). Accordingly, the pixel 95 may exhibit high QE in the photoelectric conversion unit 10.

The period p of the upper periodic structure 60 may be determined to be a predetermined size based on the wavelength and incident angle of light received by the photoelectric conversion unit 10. In addition, the period p of the upper periodic structure 60 may be formed at a length that is less than the wavelength of the light received and that allows the photoelectric conversion unit 10 to generate the diffracted light Fr.

As shown in FIG. 2, the photoelectric conversion unit 10 may be at least partially covered by the insulating film 12 and/or the interlayer dielectric film 90, which has a lower refractive index of light than the first layer 61. In at least some embodiments, the second layer 62 may include the same (or a substantially similar) material as the insulating film 12 and/or the interlayer dielectric film 90.

The period p of the upper periodic structure 60 may be formed to a length that allows the diffracted light Fr generated from the photoelectric conversion unit 10 to be totally reflected between the photoelectric conversion unit 10 and the insulating film 12.

The pixel 95 may increase the optical path length of the diffracted light Fr generated within the photoelectric conversion unit 10 by totally reflecting the diffracted light Fr in the insulating film 12. Therefore, the pixel 95 may further increase the amount of light absorbed in the photoelectric conversion unit 10.

When the period p of the upper periodic structure 60 has a length of, for example, 600 nm, a condition for the insulating film 12 to totally reflect the diffracted light Fr is that the incident angle θ (e.g., the incident angle θ with respect to the insulating film 12)≥23.7°, as shown in FIG. 2. This condition may be calculated by substituting the refractive index of the first layer 61 and the refractive index of the insulating film 12 into the well-known Snell's law.

Additionally, as shown in FIG. 2, a lower periodic structure 70, which may have the same configuration as the upper periodic structure 60, may be provided between the photoelectric conversion unit 10 and the interlayer dielectric film 90 and/or in a lower portion of the photoelectric conversion unit 10.

The inventive concepts are not limited to the at least one example embodiments described above and may be modified in various ways.

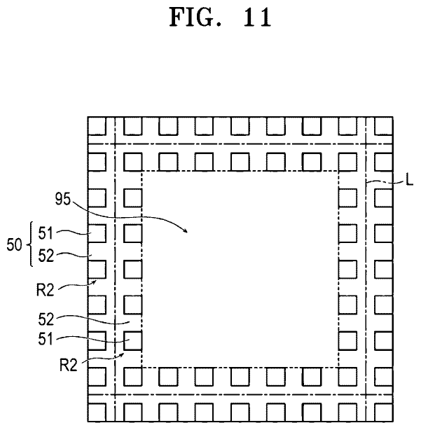

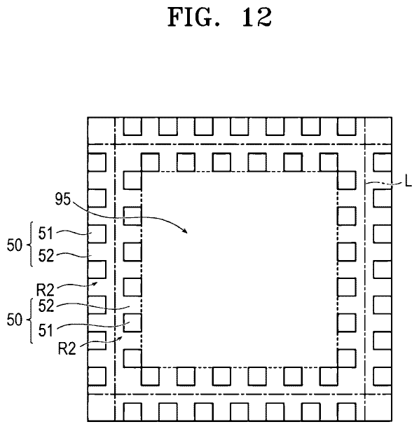

For example, in the at least one example embodiment described above, as illustrated in FIG. 4, the metal layer 51 may be positioned at the pixel boundary line L between adjacent pixels 95. However, as shown in FIGS. 11 and 12, the metal layer 51 may be positioned slightly off the pixel boundary line L between adjacent pixels 95. For example, the metal layer 51 may be positioned along an inner side of the pixel boundary line L. Accordingly, in a pixel boundary region R2 between adjacent pixels 95, the metal layers 51 may be doubly positioned based on the pixel boundary line L. At this time, the metal layers 51 doubly positioned may be arranged without misalignment on the left and right sides of the pixel boundary line L in the two-dimensional direction (e.g., arranged symmetrically with respect to the pixel boundary line L), as shown in FIG. 11. Additionally, in some embodiments, the metal layers 51 may be arranged so as to be staggered on the left and right sides of the pixel boundary line L in the two-dimensional direction (e.g., arranged asymmetrically with respect to the pixel boundary line L), as shown in FIG. 12.

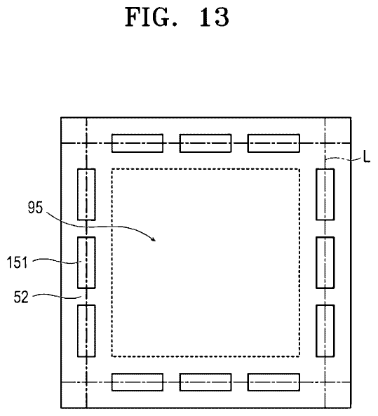

Additionally, in the at least one example embodiment described above, the metal layer 51 may be formed to be approximately square in the two-dimensional direction. However, the metal layer 51 may be formed to be a horizontally long rectangle in the two-dimensional direction, as shown in FIG. 13. Additionally, the metal layer 51 may be formed to be a vertically long rectangle.

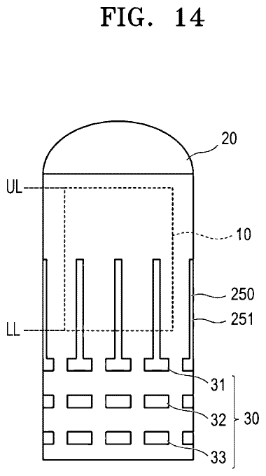

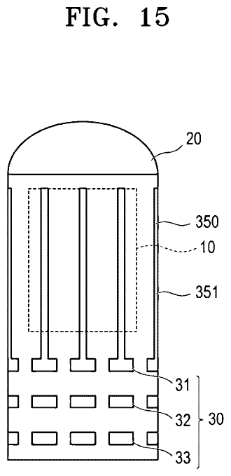

In addition, in the at least one example embodiments described above, the height H of the metal layer 51 of the first periodic structure unit 50 may be the same as and/or substantially similar to the distance from the first wiring layer 31 to the photoelectric conversion unit 10, as shown in FIGS. 4 to 6. However, as shown in FIG. 14, a height H of the metal layer 251 of a first periodic structure unit 250 may be greater than the distance from a first wiring layer 31 to the photoelectric conversion unit 10 and less than a distance from the first wiring layer 31 to the on-chip lens 20, as shown in FIG. 14. In these cases, the vertical level of the top of the metal layer 251 may be above a vertical level LL of the bottom of the photoelectric conversion unit 10 and below a vertical level UL of the top thereof. According to this configuration, the movement of light between the vicinity of the center of the photoelectric conversion unit 10 and the first wiring layer 31 may be protected against, thereby decreasing color mixing and improving the MTF value. Additionally, as shown in FIG. 15, a height H of a metal layer 351 of a first periodic structure unit 350 may be the same as the distance from the first wiring layer 31 to the on-chip lens 20. According to this configuration, the movement of light between the top of the photoelectric conversion unit 10 and the first wiring layer 31 may be protected against, thereby decreasing color mixing and improving the MTF value.

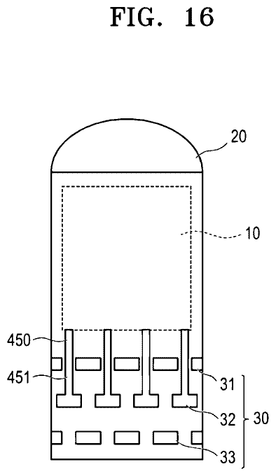

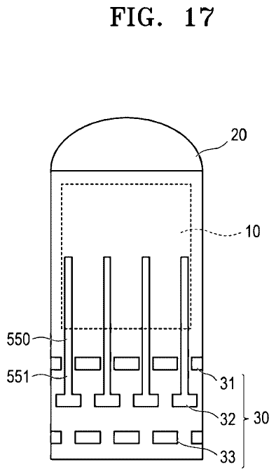

Additionally, as shown in FIG. 16, a height H of a metal layer 451 of a first periodic structure unit 450 may be the same as the distance from the first wiring layer 31 to the photoelectric conversion unit 10. That is, the vertical level of the top of the metal layer 451 may be at the vertical level LL of the bottom of the photoelectric conversion unit 10. According to this configuration, the movement of light between the bottom of the photoelectric conversion unit 10 and the second wiring layer 32 may be protected against, thereby decreasing color mixing and improving the MTF value. In addition, as shown in FIG. 17, a height H of the metal layer 551 of a first periodic structure unit 550 may be greater than the distance from a second wiring layer 32 to the photoelectric conversion unit 10 and less than a distance from the second wiring layer 32p to the on-chip lens 20. In this case, the vertical level of the top of the metal layer 551 may be above the vertical level LL of the bottom of the photoelectric conversion unit 10 and below the vertical level UL of the top thereof. According to this configuration, the movement of light between the vicinity of the center of the photoelectric conversion unit 10 and the second wiring layer 32 may be protected against, thereby decreasing color mixing and improving the MTF value.

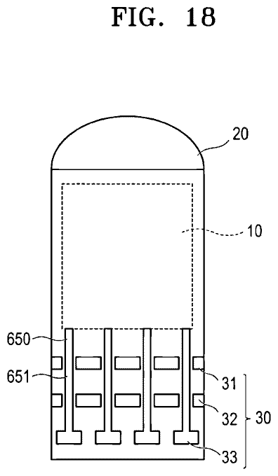

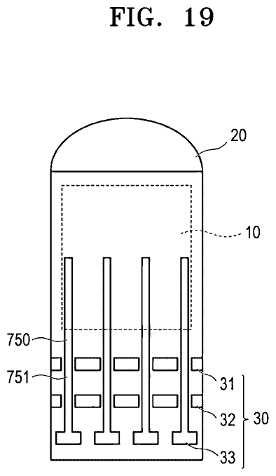

Additionally, as shown in FIG. 18, a height H of a metal layer 651 of a first periodic structure unit 650 may be the same as the distance from the third wiring layer 33 to the photoelectric conversion unit 10. In this case, the vertical level of the top of the metal layer 651 may be at the vertical level LL of the bottom of the photoelectric conversion unit 10. According to this configuration, the movement of light between the bottom of the photoelectric conversion unit 10 and the third wiring layer 33 may be protected against, thereby decreasing color mixing and improving the MTF value. In addition, as shown in FIG. 19, a height H of a metal layer 751 of a first periodic structure unit 750 may be greater than the distance from the third wiring layer 33 to the photoelectric conversion unit 10 and less than a distance from the third wiring layer 33 to the on-chip lens 20. In this case, the vertical level of the top of the metal layer 751 may be above the vertical level LL of the bottom of the photoelectric conversion unit 10 and below the vertical level UL of the top thereof. According to this configuration, the movement of light between the vicinity of the center of the photoelectric conversion unit 10 and the third wiring layer 33 may be protected against, thereby decreasing color mixing and improving the MTF value.

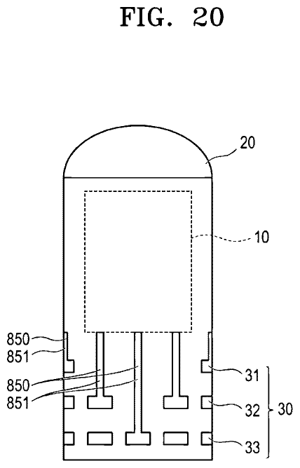

Additionally, as shown in FIG. 20, a metal layer 851 in a first periodic structure unit 850 may be different at independent island locations. Specifically, in the first periodic structure unit 850, the metal layer 851 extending vertically from the first wiring layer 31, the metal layer 851 extending vertically from the second wiring layer 32, and the metal layer 851 extending vertically from the third wiring layer 33 may be independently arranged along a perimeter of the photoelectric conversion unit 10.

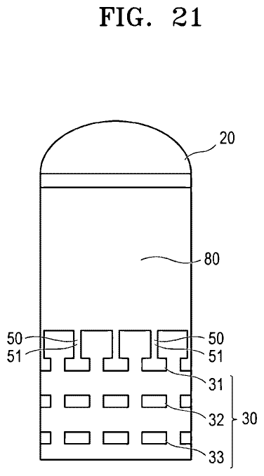

In addition, as shown in FIG. 21, a metal layer 80 may be arranged within the insulating film 12 (see FIG. 2), and the metal layer 51 of the first periodic structure unit 50 may be provided to be continuously connected to the metal layer 80. According to this configuration, the movement of light through the insulating film 12 may be protected against, thereby decreasing color mixing and improving the MTF value.

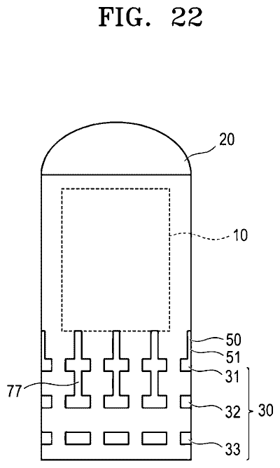

In addition, as shown in FIG. 22, the solid-state imaging device may further include a second periodic structure unit 77 provided between the second wiring layer 32 and the first wiring layer 31. The second periodic structure unit 77 may have the same periodicity as that of the first periodic structure unit 50. According to this configuration, the movement of light between the first wiring layer 31 and the second wiring layer 32 may be protected against, thereby decreasing color mixing and improving the MTF value.

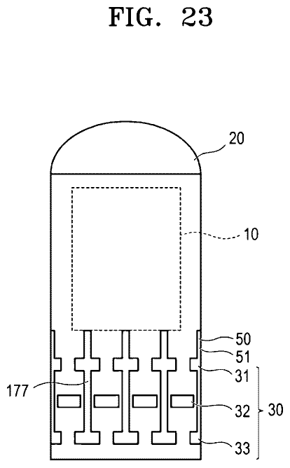

In addition, as shown in FIG. 23, the solid-state imaging device may further include a second periodic structure unit 177 provided between the third wiring layer 33 and the first wiring layer 31. The second periodic structure unit 177 may have the same periodicity as that of the first periodic structure unit 50. According to this configuration, the movement of light between the first wiring layer 31 and the third wiring layer 33 may be protected against, thereby decreasing color mixing and improving the MTF value.

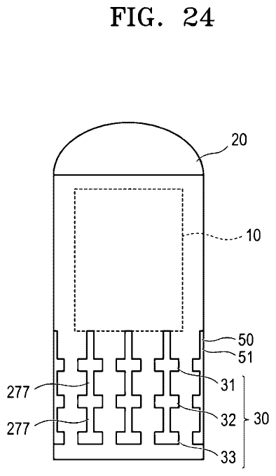

In addition, as shown in FIG. 24, the solid-state imaging device may further include a second periodic structure unit 277 provided between the first wiring layer 31 and the second wiring layer 32 and between the second wiring layer 32 and the third wiring layer 33. The second periodic structure unit 277 is a group of second periodic structures, and may also be referred as a “second group of periodic structures.” The second periodic structure unit 277 may have the same periodicity as that of the first periodic structure unit 50. According to this configuration, the movement of light between the first wiring layer 31 and the second wiring layer 32 and between the second wiring layer 32 and the third wiring layer 33 may be protected against, thereby decreasing color mixing and improving the MTF value.

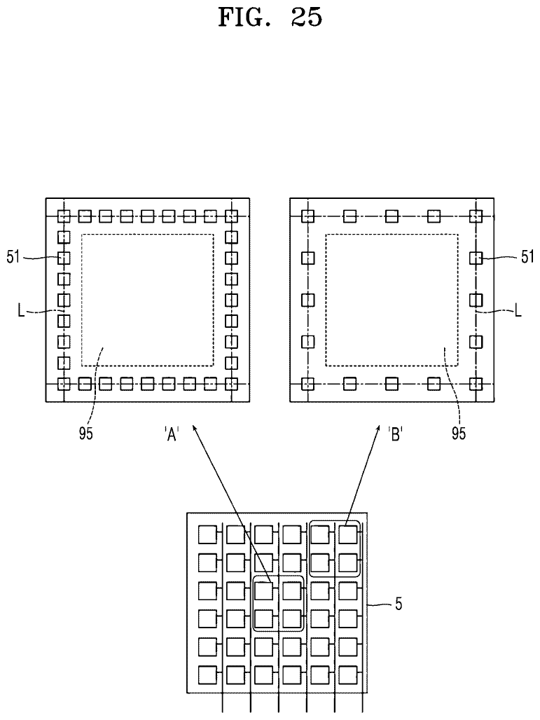

Additionally, in the at least one example embodiments described above, the shape and arrangement of the metal layers 51 in all pixels 95 may have the same shape. On the other hand, as shown in FIG. 25, the shape or period of the metal layers 51 may be different from each other in a central portion (e.g., ‘A’ portion) and a peripheral portion (e.g., ‘B’ portion) of the pixel region 5. For example, the period of the metal layers 51 in the central portion (e.g., ‘A’ portion) of the pixel region 5 may be less than the period of the metal layers 51 in the peripheral portion (e.g., ‘B’ portion). That is, the metal layers 51 in the central portion (‘A’ portion) may be arranged more densely than the metal layers 51 in the peripheral portion (‘B’ portion).

In addition, in the example embodiments described above, the solid-state imaging device 1 may include the upper and/or lower periodic structures 60 and 70, but in some example embodiments, at least one of the upper and/or lower periodic structures 60 and 70 may not have periodic structures.

While the inventive concepts have been particularly shown and described with reference to embodiments thereof, it will be understood that various changes in form and details may be made therein without departing from the spirit and scope of the following claims.

What is claimed is:

1. A solid-state imaging device comprising a plurality of pixels, each of the plurality of pixels comprising:
a photoelectric conversion unit configured to generate electric charges from incident light;
an on-chip lens on an upper side of the photoelectric conversion unit;
a plurality of wiring layers under a lower side of the photoelectric conversion unit, the plurality of wiring layers configured to extract the electric charges generated by the photoelectric conversion unit;
an interlayer dielectric film between the plurality of wiring layers and between the plurality of wiring layers and the photoelectric conversion unit; and
a first periodic structure unit including metal layers and dielectric layers alternating sequentially in a circumferential direction along a periphery of the photoelectric conversion unit, at least a portion of the first periodic structure unit in a region between the photoelectric conversion unit and the plurality of wiring layers.

2. The solid-state imaging device of claim 1, wherein the metal layers of the first periodic structure unit are periodically formed in the circumferential direction of the photoelectric conversion unit, and a pitch of the metal layers is less than a wavelength of light received by the photoelectric conversion unit.

3. The solid-state imaging device of claim 2, wherein the pitch of the metal layers is in a range of about 200 nanometers (nm) to about 1,000 nm.

4. The solid-state imaging device of claim 1, wherein the metal layers of the first periodic structure unit comprise at least one of tungsten, aluminum, and copper, and
the dielectric layers of the first periodic structure unit comprise at least one of silicon dioxide (SiO₂), silicon nitride (SiN), aluminum oxide (AlO), tantalum oxide (TaO), titanium nitride (TiN), and titanium oxide (TiO).

5. The solid-state imaging device of claim 1, wherein tops of the metal layers of the first periodic structure unit are above a bottom of the photoelectric conversion unit and below a top of the photoelectric conversion unit.

6. The solid-state imaging device of claim 1, wherein the plurality of wiring layers comprise a first wiring layer close and a second wiring layer farther away from the photoelectric conversion unit than the first wiring layer, and
the metal layers of the first periodic structure unit extend vertically from at least one of the first wiring layer or the second wiring layer.

7. The solid-state imaging device of claim 6, wherein the metal layers of the first periodic structure unit extending vertically from the first wiring layer and the metal layers of the first periodic structure unit extending vertically from the second wiring layer are each formed in the circumferential direction of the photoelectric conversion unit as separate islands.

8. The solid-state imaging device of claim 1, further comprising:
a second periodic structure unit having a same periodicity as the first periodic structure unit,
wherein the plurality of wiring layers comprise a first wiring layer and a second wiring layer further away from the photoelectric conversion unit than the first wiring layer, and
wherein the second periodic structure unit comprises metal layers and dielectric layers in a second region, the second region between the first wiring layer and the second wiring layer.

9. The solid-state imaging device of claim 1, further comprising:
an upper periodic structure in which a plurality of first layers and a plurality of second layers alternate in a two-dimensional direction at an upper portion of the photoelectric conversion unit,
wherein the plurality of second layers has a lower refractive index of light than the plurality first of layers,
the two-dimensional direction is orthogonal to a vertical direction, and
periods of the plurality of first layers and the plurality of second layers are configured to diffract the incident light.

10. The solid-state imaging device of claim 9, further comprising:
a lower periodic structure at a lower portion of the photoelectric conversion unit, the lower periodic structure having a same configuration as the upper periodic structure.

11. A solid-state imaging device comprising a pixel region that comprises a plurality of pixels arranged in two dimensions, the solid-state imaging device comprising:
photoelectric conversion units, each of the photoelectric conversion units in a corresponding pixel of the plurality of pixels;
an insulating film between the photoelectric conversion units, the insulating film configured to insulate each of the plurality of pixels from adjacent pixels of the plurality of pixels;
on-chip lenses, each of the on-chip lenses on an upper side of a corresponding one of the photoelectric conversion units;
a plurality of wiring layers below the photoelectric conversion units, the plurality of wiring layers configured to extracting electric charges generated by the photoelectric conversion units from incident light;
an interlayer dielectric film between the plurality of wiring layers and between the plurality of wiring layers and the photoelectric conversion units; and
a first periodic structure unit in a region between the photoelectric conversion units and the plurality of wiring layers, the first periodic structure unit comprising metal layers spaced apart from each along a pixel boundary region between the adjacent pixels.

12. The solid-state imaging device of claim 11, wherein the metal layers of the first periodic structure unit define a pixel boundary line within the pixel boundary region.

13. The solid-state imaging device of claim 12, wherein the metal layers of the first periodic structure unit are arranged such that the metal layers include a first portion and a second portion are separated by the pixel boundary line.

14. The solid-state imaging device of claim 13, wherein the first portion and the second portion are symmetrically with respect to the pixel boundary line.

15. The solid-state imaging device of claim 13, wherein the first portion and the second portion are asymmetrically with respect to the pixel boundary line.

16. The solid-state imaging device of claim 11, wherein for each of the photoelectric conversion units, the metal layers of the first periodic structure unit are arranged periodically in a circumferential direction, and a pitch of the metal layers is less than a wavelength of the incident light received.

17. The solid-state imaging device of claim 11, wherein tops of the metal layers of the first periodic structure unit are above bottoms of the photoelectric conversion units and below tops of the photoelectric conversion units.

18. The solid-state imaging device of claim 11, further comprising:
an upper periodic structure in which a plurality of first layers and a plurality of second layers alternate in a two-dimensional direction orthogonal at an upper portion of the photoelectric conversion units,
wherein the plurality of second layers has a lower refractive index of light than the plurality of first layers,
the two-dimensional direction is orthogonal to a vertical direction, and
periods of the plurality of first layers and the plurality of second layers are configured to diffract the incident light.

19. A solid-state imaging device comprising a pixel region that comprises a plurality of pixels arranged in two dimensions, the solid-state imaging device comprising:
photoelectric conversion units, each of the photoelectric conversion units in a corresponding pixel of the plurality of pixels;
an insulating film between the photoelectric conversion units, the insulating film configured to insulate each of the plurality of pixels from adjacent pixels of the plurality of pixels;
on-chip lenses, each of the on-chip lenses on an upper side of a corresponding one of the photoelectric conversion units;
a plurality of wiring layers below on a lower side of the photoelectric conversion units, the plurality of wiring layers configured to and extracting electric charges generated by the photoelectric conversion units from incident light;
an interlayer dielectric film between the plurality of wiring layers and between the plurality of wiring layers and the photoelectric conversion units; and
a first periodic structure unit in a region between the photoelectric conversion units and the plurality of wiring layers, the first periodic structure unit comprising metal layers spaced apart from each other along a pixel boundary region between the adjacent pixels,
wherein a period of the metal layers of the first periodic structure unit in a central portion of the pixel region is different from a period of the metal layers of the first periodic structure unit in a peripheral portion of the pixel region.

20. The solid-state imaging device of claim 19, wherein the period of the metal layers of the first periodic structure unit in the central portion of the pixel region is less than the period of the metal layers of the first periodic structure unit in the peripheral portion.
